(19) United States
(12) Patent Application Publication
(10) Pub. No.: US 2026/0255978 A1
(43) Pub. Date: Aug. 27, 2026

(54) SEMICONDUCTOR PACKAGE INCLUDING SHIELDING FILM

(71) Applicant: Samsung Electronics Co., Ltd., Suwon-si (KR)

(72) Inventors: Dongkuk Lee, Suwon-si (KR); Seungduk Baek, Suwon-si (KR)

(73) Assignee: Samsung Electronics Co., Ltd., Suwon-si (KR)

(21) Appl. No.: 19/547,134

(22) Filed: Feb. 23, 2026

(30) Foreign Application Priority Data
Feb. 24, 2025 (KR) 10-2025-0023885

(51) Int. Cl. H10W 42/20; H10W 70/63; H10W 74/10; H10W 90/10

(52) U.S. Cl. CPC H10W 42/276; H10W 70/63; H10W 74/131; H10W 90/10

(57) ABSTRACT

A semiconductor package includes a package substrate including a wiring pattern; an interposer substrate located on the package substrate and including a body, a through-electrode passing through the body, a redistribution pattern connected to the through-electrode, a redistribution insulating layer surrounding at least a portion of the redistribution pattern, and an interposer substrate pad; a first chip on the interposer substrate; a second chip spaced apart from the first chip in a horizontal direction on the interposer substrate; and a shielding film covering an exposed surface of the first chip and an exposed surface of the second chip, wherein the through-electrode includes a ground through-electrode, the redistribution pattern includes a ground redistribution pattern, the interposer substrate pad includes a ground interposer substrate pad, and the shielding film is in contact with the ground interposer substrate pad.

### CROSS-REFERENCE TO RELATED APPLICATION

This present application claims priority to and the benefit under 35 U.S.C. § 119(a)-(d) of Korean Patent Application No. 10-2025-0023885, filed on Feb. 24, 2025, in the Korean Intellectual Property Office, the entire disclosure of which is incorporated herein by reference.

### FIELD

The disclosed concepts relate to a semiconductor package, and more particularly, to a semiconductor package including an electromagnetic interference (EMI) shielding film.

### BACKGROUND

Recently, due to the miniaturization of process technology and the diversification of functions, chip sizes of micro devices have decreased and the number of input/output terminals has increased, and thus the electrode connection pitch has been increasingly miniaturized. In addition, as the convergence of various functions has accelerated, system-level packaging technology for integrating multiple devices into a single package has emerged.

However, system-level packaging technology may cause EMI between components as the operating speeds of electronic components increase and various functions are added to the electronic components, and research has continued to reduce EMI between components.

### SUMMARY

The disclosed concepts provide a semiconductor package having improved effect in blocking electromagnetic interference between components.

In addition, the technical goals to be achieved by the disclosed concept are not limited to the technical goals mentioned above, and other technical goals may be clearly understood by one of ordinary skill in the art from the following descriptions.

In order to achieve the technical goals, the disclosed concept provides the following semiconductor package.

According to aspects of the disclosed concepts, there is provided a semiconductor package including: a package substrate including a wiring pattern; an interposer substrate located on the package substrate and including a body, a through-electrode passing through the body, a redistribution pattern connected to the through-electrode, a redistribution insulating layer surrounding at least a portion of the redistribution pattern, and an interposer substrate pad; a first chip on the interposer substrate; a second chip spaced apart from the first chip in a horizontal direction on the interposer substrate; and a shielding film covering an exposed surface of the first chip and an exposed surface of the second chip, wherein the through-electrode includes a ground through-electrode, the redistribution pattern includes a ground redistribution pattern, the interposer substrate pad includes a ground interposer substrate pad, and the shielding film is in contact with the ground interposer substrate pad.

According to aspects of the disclosed concepts, there is provided a semiconductor package including: a package substrate including a first wiring pattern and a second wiring pattern; a first external connection terminal and a second external connection terminal located on a lower surface of the package substrate; an interposer substrate located on an upper surface of the package substrate, the interposer substrate including a body, a first through-electrode and a second through-electrode passing through the body, a first redistribution pattern electrically connected to the first through-electrode, a second redistribution pattern electrically connected to the second through-electrode, a redistribution insulating layer, a first interposer substrate pad connected to the first redistribution pattern on the redistribution insulating layer, and a second interposer substrate pad connected to the second redistribution pattern on the redistribution insulating layer; a first substrate connection bump and a second substrate connection bump located between the package substrate and the interposer substrate; a first chip on the interposer substrate; a second chip spaced apart from the first chip in a horizontal direction on the interposer substrate; and a shielding film covering an upper surface of the interposer substrate, an upper surface and a side surface of the first chip, and an upper surface and a side surface of the second chip, wherein the first wiring pattern, the first external connection terminal, the first through-electrode, the first redistribution pattern, the first substrate connection bump, and the first interposer substrate pad transmit a ground signal.

According to aspects of the disclosed concepts, there is provided a semiconductor package including: a package substrate including a first wiring pattern and a second wiring pattern; a first external connection terminal and a second external connection terminal located on a lower surface of the package substrate; an interposer substrate located on an upper surface of the package substrate, the interposer substrate including a body, a first through-electrode and a second through-electrode passing through the body, a first redistribution pattern electrically connected to the first through-electrode, a second redistribution pattern electrically connected to the second through-electrode, a redistribution insulating layer, a first interposer substrate pad connected to the first redistribution pattern on the redistribution insulating layer, and a second interposer substrate pad connected to the second redistribution pattern on the redistribution insulating layer; a first substrate connection bump and a second substrate connection bump located between the package substrate and the interposer substrate; an underfill material layer surrounding the first substrate connection bump and the second substrate connection bump; a first chip on the interposer substrate; a second chip spaced apart from the first chip in a horizontal direction on the interposer substrate; a shielding film covering an upper surface of the interposer substrate, an upper surface and a side surface of the first chip, and an upper surface and a side surface of the second chip; and a molding member covering an upper surface of the package substrate, a side surface and an upper surface of the interposer substrate, and the shielding film, wherein the first wiring pattern, the first external connection terminal, the first through-electrode, the first redistribution pattern, the first substrate connection bump, and the first interposer substrate pad transmit a ground signal, the shielding film and the molding member are located between the first chip and the second chip, and each of the first interposer substrate pad, the first through-electrode, the first substrate connection bump, and the first external connection terminal does not overlap each of the first chip and the second chip in a vertical direction.

According to aspects of the disclosed concepts, there is provided a method of manufacturing a semiconductor package including: providing a package substrate including a wiring pattern; providing an interposer substrate on the package substrate and including a body, a through-electrode passing through the body, a redistribution pattern connected to the through-electrode, a redistribution insulating layer surrounding at least a portion of the redistribution pattern, and an interposer substrate pad; providing a first chip on the interposer substrate; providing a second chip spaced apart from the first chip in a horizontal direction on the interposer substrate; and providing a shielding film covering an exposed surface of the first chip and an exposed surface of the second chip, wherein the through-electrode includes a ground through-electrode, the redistribution pattern includes a ground redistribution pattern, the interposer substrate pad includes a ground interposer substrate pad, and the shielding film is in contact with the ground interposer substrate pad.

### BRIEF DESCRIPTION OF THE DRAWINGS

Embodiments will be more clearly understood from the following detailed description taken in conjunction with the accompanying drawings in which:

FIG. 1A is a schematic plan view of a semiconductor package according to embodiments;

FIG. 1B is a schematic plan view of a semiconductor package according to embodiments;

FIG. 2 is a cross-sectional view of the semiconductor package taken along line A1-A1′ of FIG. 1B;

FIG. 3 is a schematic diagram schematically showing embodiments of a first chip of FIG. 2;

FIG. 4 is a schematic diagram schematically showing embodiments of the first chip of FIG. 2;

FIG. 5 is a schematic cross-sectional view of a semiconductor package according to embodiments;

FIG. 6 is a schematic cross-sectional view of a semiconductor package according to embodiments;

FIG. 7 is a schematic cross-sectional view of a semiconductor package according to embodiments;

FIG. 8 is a schematic cross-sectional view of a semiconductor package according to embodiments;

FIG. 9 is a schematic cross-sectional view of a semiconductor package according to embodiments;

FIGS. 10 to 12 are cross-sectional views illustrating a method of manufacturing a semiconductor package, according to embodiments; and

FIGS. 13 to 15 are cross-sectional views illustrating a method of manufacturing a semiconductor package, according to embodiments.

### DETAILED DESCRIPTION

Hereinafter, embodiments will be described in detail with reference to the attached drawings. The same reference numerals are used for the same components in the drawings, and redundant descriptions thereof are omitted.

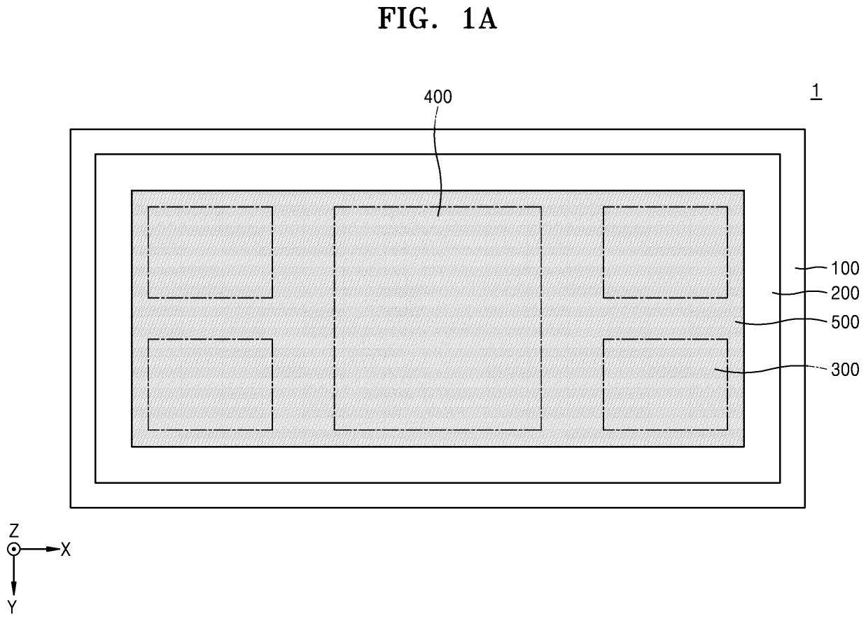

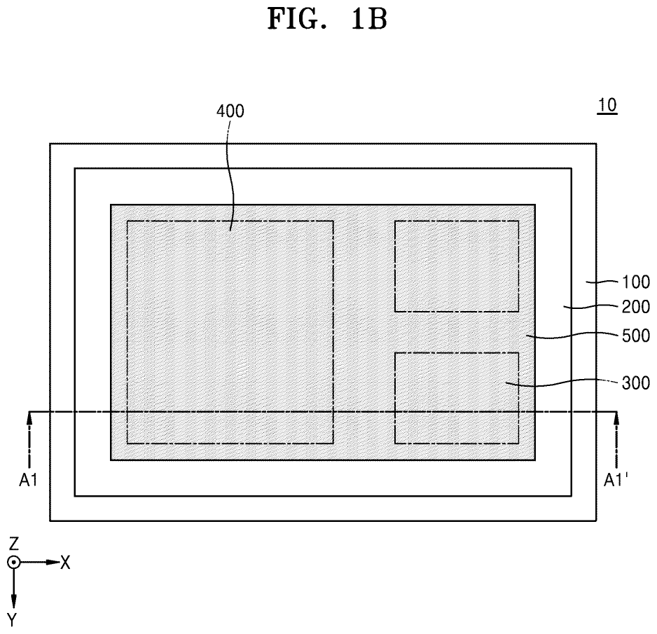

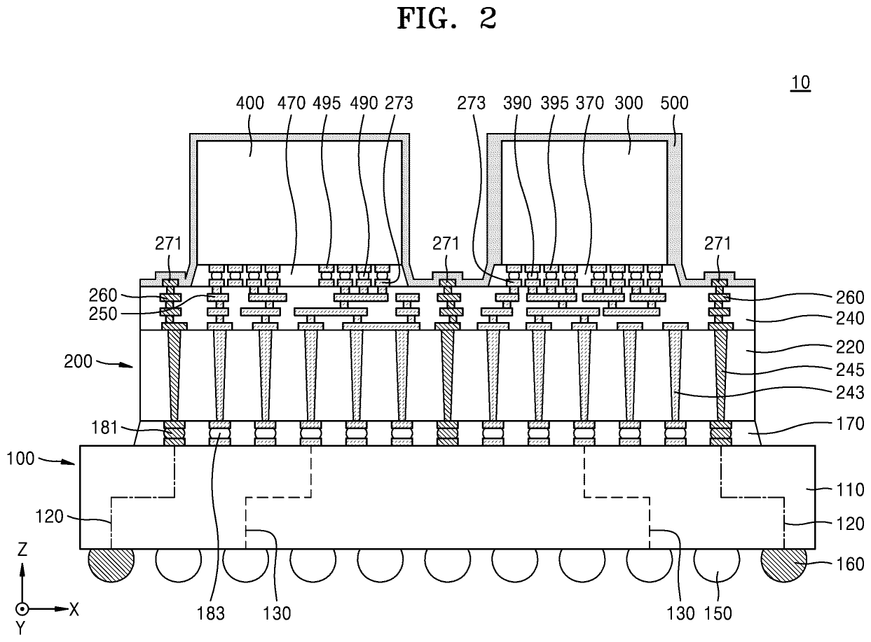

FIG. 1A is a schematic plan view of a semiconductor package according to embodiments. FIG. 1B is a schematic plan view of a semiconductor package according to embodiments. FIG. 2 is a cross-sectional view of the semiconductor package taken along line A1-A1′ of FIG. 1B.

Referring to FIGS. 1A to 2, semiconductor packages 1 and 10 may each include a package substrate 100, an interposer substrate 200, a first chip 300, a second chip 400, and a shielding film 500. According to embodiments, the package substrate 100 may be located below the interposer substrate 200 and may be electrically connected to the interposer substrate 200 and each of external connection terminals 150 and 160. The semiconductor package 1 illustrated in FIG. 1A and the semiconductor package 10 illustrated in FIG. 1B respectively show plan views of embodiments of the semiconductor packages 1 and 10 each including the package substrate 100, the interposer substrate 200, the first chip 300, the second chip 400, and the shielding film 500. The following description will be based on FIG. 1B.

Hereinafter, in the drawings, the X-axis direction and the Y-axis direction represent directions parallel to the surface of the package substrate 100, and the X-axis direction and the Y-axis direction may be understood as directions perpendicular to one another. The Z-axis direction may represent a direction perpendicular to the upper or lower surface of the package substrate 100, in other words, a direction perpendicular to the X-Y plane. In addition, a first horizontal direction, a second horizontal direction, and a vertical direction in the drawings may be understood as follows. The first horizontal direction may be understood as the X-axis direction, the second horizontal direction may be understood as the Y-axis direction, and the vertical direction may be understood as the Z-axis direction.

The package substrate 100 may be a substrate on which the interposer substrate 200 is mounted. In some embodiments, the package substrate 100 may be a motherboard on which various types of semiconductor chips and packages are mounted. In addition, in some embodiments, the package substrate 100 may be a substrate that functions as an intermediate bridge receiving an electrical signal from the interposer substrate 200 and transmitting the electrical signal to an external device. In addition, the package substrate 100 may also be connected to ground.

According to embodiments, the package substrate 100 may be a printed circuit board (PCB) that includes wiring patterns 120 and 130 and an insulating layer 110 surrounding the wiring patterns 120 and 130. In this case, the wiring patterns 120 and 130 may include copper, nickel, stainless steel, or beryllium copper, and the insulating layer 110 may include at least one material selected from phenol resin, epoxy resin, and polyimide. The insulating layer 110 may include, for example, at least one material selected from flame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

According to embodiments, the wiring patterns 120 and 130 may include a first wiring pattern 120 that transmits a ground signal, and a second wiring pattern 130 that transmits a power/signal. According to embodiments, the second wiring pattern 130 may transmit other signals in addition to the power/signal. In the present specification, the first wiring pattern 120 may also be referred to as a ground wiring pattern.

External connection terminals 150 and 160 may be located on the lower surface of the package substrate 100. The external connection terminals 150 and 160 may be mounted on the lower surface of the package substrate 100 and configured to transmit signals received from the wiring patterns 120 and 130 of the package substrate 100 to an external device. The external connection terminals 150 and 160 may include a first external connection terminal 160 connected to the first wiring pattern 120, and a second external connection terminal 150 connected to the second wiring pattern 130. According to embodiments, the first external connection terminal 160 may transmit a ground signal. In some embodiments, the first external connection terminal 160 may be directly connected to the ground. The second external connection terminal 150 may transmit a power/signal. According to embodiments, the second external connection terminal 150 may transmit other signals in addition to the power/signal. In the present specification, the first external connection terminal 160 may be referred to as a ground external connection terminal.

According to embodiments, each of the external connection terminals 150 and 160 may be formed as a solder ball. However, according to embodiments, each of the external connection terminals 150 and 160 may have a structure including a pillar and solder. Each of the external connection terminals 150 and 160 may include at least one of copper (Cu), silver (Ag), gold (Au), and tin (Sb).

The interposer substrate 200 may be mounted on the package substrate 100. According to embodiments, the interposer substrate 200 may be mounted on the package substrate 100 in a flip chip manner through substrate connection bumps 181 and 183. According to embodiments, an underfill material layer 170 may be arranged between the interposer substrate 200 and the package substrate 100 to surround the substrate connection bumps 181 and 183. The underfill material layer 170 may include, for example, an epoxy resin formed by a capillary under-fill method. However, in some embodiments, a molding member may be directly filled into a gap between the interposer substrate 200 and the package substrate 100 through a molded under-fill process. In this case, the underfill material layer 170 may be omitted.

According to embodiments, the substrate connection bumps 181 and 183 may include a first substrate connection bump 181 connected to the first wiring pattern 120, and a second substrate connection bump 183 connected to the second wiring pattern 130. The first substrate connection bump 181 may transmit a ground signal between the interposer substrate 200 and the package substrate 100. The second substrate connection bump 183 may transmit a power/signal between the interposer substrate 200 and the package substrate 100. According to embodiments, the second substrate connection bump 183 may transmit other signals in addition to the power/signal. In the present specification, the first substrate connection bump 181 may be referred to as a ground substrate connection bump.

The interposer substrate 200 may be formed based on silicon and may electrically connect the first chip 300 and the second chip 400 mounted on the interposer substrate 200. That is, the interposer substrate 200 may function as a connection passage that electrically connects the first chip 300 to the second chip 400. According to embodiments, when the first chip 300 and the second chip 400 are different types of chips or chip structures, the first chip 300 and the second chip 400 may exchange electrical signals with one another through the interposer substrate 200.

The interposer substrate 200 may include a body 220, through-electrodes 243 and 245, a redistribution insulating layer 240, and redistribution patterns 250 and 260. The body 220 may include an upper surface and a lower surface. The body 220 may include silicon (Si), for example, crystalline silicon, polycrystalline silicon, or amorphous silicon. Alternatively, the body 220 may include a semiconductor element, such as germanium (Ge), or a compound semiconductor, such as silicon carbide (SiC), gallium arsenide (GaAs), indium arsenide (InAs), or indium phosphide (InP). The body 220 may have a silicon on insulator (SOI) structure. For example, the body 220 may include a buried oxide (BOX) layer.

The through-electrodes 243 and 245 may pass through the body 220 in a vertical direction (the Z-axis direction). The through-electrodes 243 and 245 may extend from the upper surface of the body 220 toward the lower surface thereof in the vertical direction (the Z-axis direction) and may be electrically connected to the substrate connection bumps 181 and 183. According to embodiments, each of the through-electrodes 243 and 245 may have a tapered shape in which the horizontal width decreases or increases as the level in the vertical direction (the Z-axis direction) increases. According to embodiments, each of the through-electrodes 243 and 245 may include a through silicon via (TSV).

The through-electrodes 243 and 245 may include a first through-electrode 245 connected to the first substrate connection bump 181, and a second through-electrode 243 connected to the second substrate connection bump 183. The first through-electrode 245 may be configured to transmit a ground signal, and the second through-electrode 243 may be configured to transmit a power/signal. According to embodiments, the second through-electrode 243 may transmit other signals in addition to the power/signal. In the present specification, the first through-electrode 245 may also be referred to as a ground through-electrode.

The redistribution insulating layer 240 may be located on the upper surface of the body 220. The redistribution insulating layer 240 may surround at least portions of the redistribution patterns 250 and 260. According to embodiments, the redistribution insulation layer 240 may be provided by stacking a plurality of layers in the vertical direction (the Z-axis direction). The redistribution patterns 250 and 260 may function as electrical connection passages passing through the upper surface and the lower surface of the redistribution insulation layer 240.

According to embodiments, the redistribution insulation layer 240 may be formed from a photo imageable dielectric (PID) or a photosensitive polyimide (PSPI).

According to embodiments, each of the redistribution patterns 250 and 260 may include a metal or an alloy of metals, such as, but not limited to, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and the like, and in some embodiments, the redistribution patterns 250 and 260 may be formed by depositing a metal or an alloy of metals on a seed layer including copper, titanium, titanium nitride, or titanium tungsten. Each of the redistribution patterns 250 and 260 may include a redistribution line pattern and a redistribution via pattern. The redistribution line pattern may have a shape extending in a horizontal direction along at least one surface among the upper surface and the lower surface of each of the plurality of redistribution insulation layers 240 stacked in the vertical direction (the Z-axis direction). The redistribution via pattern may have a shape extending through the redistribution insulation layer 240 in the vertical direction (the Z-axis direction). The redistribution via pattern may electrically connect redistribution line patterns located at different vertical levels. In some embodiments, at least some of the redistribution line patterns may be formed together with some of the redistribution via patterns to form a single body.

The redistribution patterns 250 and 260 may include a first redistribution pattern 260 connected to the first through-electrode 245, and a second redistribution pattern 250 connected to the second through-electrode 243. The first redistribution pattern 260 may be configured to transmit a ground signal, and the second redistribution pattern 250 may be configured to transmit power/a signal. In the present specification, the first redistribution pattern 260 may also be referred to as a ground redistribution pattern.

Interposer substrate pads 271 and 273 may be located on the upper surface of the interposer substrate 200. According to embodiments, the interposer substrate pads 271 and 273 may be exposed from the redistribution insulation layer 240 in the vertical direction (the Z-axis direction)). In some embodiments, at least a portion of the side surface of each of the interposer substrate pads 271 and 273 may be exposed from the redistribution insulation layer 240.

According to embodiments, the interposer substrate pads 271 and 273 may include a first interposer substrate pad 271 connected to the first redistribution pattern 260, and a second interposer substrate pad 273 connected to the second redistribution pattern 25. The first interposer substrate pad 271 may be connected to the shielding film 500 and configured to transmit a ground signal. The second interposer substrate pad 273 may be connected to at least one of a first chip connection bump 390 and a second chip connection bump 490. In the present specification, the first interposer substrate pad 271 may also be referred to as a ground interposer substrate pad.

The first chip 300 may be located on the interposer substrate 200. According to embodiments, the first chip 300 may be mounted on the interposer substrate 200 in a flip chip manner through the first chip connection bump 390, such as a micro bump, and a first chip pad 395. According to embodiments, an underfill material layer 370 may be arranged between the first chip 300 and the interposer substrate 200 to surround the first chip connection bump 390. The underfill material layer 370 may include, for example, an epoxy resin formed by a capillary underfill method.

The first chip 300 may be a semiconductor chip or a chip stack structure. According to embodiments, when the first chip 300 is a semiconductor chip, the first chip 300 may be a memory chip. The memory chip may be, for example, a volatile memory chip, such as dynamic random access memory (DRAM) or static random access memory (SRAM), or a nonvolatile memory chip, such as phase-change random access memory (PRAM), magnetoresistive random access memory (MRAM), ferroelectric random access memory (FeRAM), or resistive random access memory (RRAM).

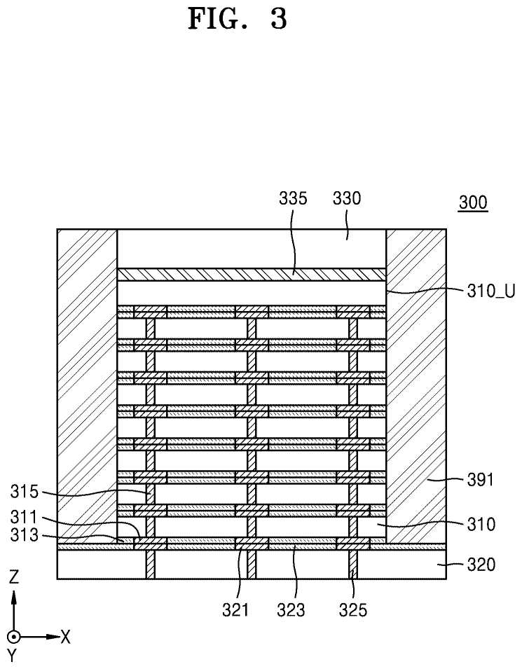

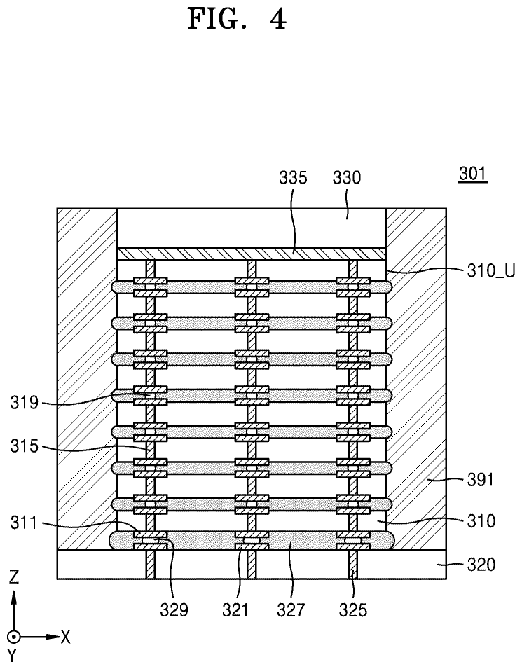

According to embodiments, when the first chip 300 is a chip stack structure, the chip stack structure may be a high bandwidth memory package (HBM) or a wire bonding memory package in which a plurality of memory chips are stacked in the vertical direction (the Z-axis direction). This will be described in detail with reference to FIGS. 3 and 4.

The second chip 400 may be apart from the first chip 300 in the horizontal direction (the X-axis direction and/or the Y-axis direction) and mounted on the interposer substrate 200. The second chip 400 may be mounted on the interposer substrate 200 in a flip chip manner through the second chip connection bump 490, such as a micro bump, and a second chip pad 495. According to embodiments, an underfill material layer 470 may be arranged between the second chip 400 and the interposer substrate 200 to surround the second chip connection bump 490. The underfill material layer 470 may include, for example, an epoxy resin formed by using a capillary underfill method.

According to embodiments, the second chip 400 may be a logic chip. The logic chip may be, for example, a microprocessor, such as a central processing unit (CPU), a graphics processing unit (GPU), or an application processor (AP), an analog device, or a digital signal processor.

However, the first chip 300 is not limited to a memory chip, and the second chip 400 is not limited to a logic chip. In some embodiments, each of the first chip 300 and the second chip 400 may be a memory chip or a logic chip, and the first chip 300 may be a logic chip and the second chip 400 may be a memory chip.

Each of the first external connection terminal 160, the first substrate connection bump 181, the first through-electrode 245, and the first interposer substrate pad 271 may be provided in plurality. Each of the first external connection terminal 160, the first substrate connection bump 181, the first through-electrode 245, and the first interposer substrate pad 271 may be located in the lateral direction of the first chip 300, between the first chip 300 and the second chip 400, and in the lateral direction of the second chip 400. In this case, the lateral direction may be understood as the opposite direction to a direction in which the first chip 300 and the second chip 400 face one another. For example, the lateral direction of the first chip 300 may be understood as the opposite lateral direction to the direction in which the first chip 300 and the second chip 400 face one another, and the lateral direction of the second chip 400 may be understood as the opposite lateral direction to the direction in which the second chip 400 and the first chip 300 face one another.

Each of the first external connection terminal 160, the first substrate connection bump 181, the first through-electrode 245, and the first interposer substrate pad 271 may not overlap each of the first chip 300 and the second chip 400 in the vertical direction (the Z-axis direction).

The shielding film 500 may be configured to prevent electromagnetic interference. According to embodiments, the shielding film 500 may be configured to shield electromagnetic interference (EMI). The shielding film 500 may include a conductive material including at least one selected from the group consisting of metals and ceramics, and specifically, may include at least one selected from the group consisting of copper (Cu), gold (Au), silver (Ag), and titanium (Ti).

In addition, the shielding film 500 may include a conductive resin. The conductive resin may include a combination of a carbon-based resin to which at least one of aluminum, ceramic, or silicon is added.

The shielding film 500 may cover the surface of the first chip 300 and the surface of the second chip 400. According to embodiments, the shielding film 500 may cover, without gaps, the surface exposed from the underfill material layer 370 in the first chip 300. In addition, the shielding film 500 may cover, without gaps, the surface exposed from the underfill material layer 470 in the second chip 400.

The shielding film 500 may cover the upper surface and the side surface of the first chip 300, and may cover the upper surface and the side surface of the second chip 400.

According to embodiments, the shielding film 500 may cover the upper surface of the interposer substrate 200 in addition to the surface of each of the first chip 300 and the second chip 400. In this case, the shielding film 500 may cover the first interposer substrate pad 271. According to embodiments, the shielding film 500 covering the first interposer substrate pad 271 may be located at a higher vertical level than the shielding film 500 covering the upper surface of the redistribution insulating layer 240. Because the first interposer substrate pad 271 is located to protrude in the vertical direction (the Z-axis direction) from the upper surface of the redistribution insulating layer 240, the shielding film 500 covering the first interposer substrate pad 271 may be located at a higher vertical level than the shielding film 500 covering the upper surface of the redistribution insulating layer 240. Because the shielding film 500 covers the side surface of the first interposer substrate pad 271, the shielding film 500 that comes into lateral contact with the first interposer substrate pad 271 may extend in the vertical direction (the Z-axis direction).

The shielding film 500 may cover the surfaces of the underfill material layers 370 and 470 exposed from each of the interposer substrate 200, the first chip 300, and the second chip 400. In this case, the shielding film 500 covering the underfill material layers 370 and 470 may have a slope. The slope may form a certain angle with the upper surface of the interposer substrate 200.

The semiconductor package 10 according to the disclosed concept may reduce electromagnetic interference between the first chip 300 and the second chip 400 because the shielding film 500 covers, without any gaps, the components of the semiconductor package 10, that is, the first chip 300 and the second chip 400 in the embodiment according to FIGS. 1 and 2. In addition, because the shielding film 500 is connected to the first interposer substrate pad 271, the first redistribution pattern 260, the first through-electrode 245, the first substrate connection bump 181, the first wiring pattern 120, and the first external connection terminal 160, which transmit a ground signal, the shielding film 500 may be grounded without forming a separate ground pattern.

In addition, because, for efficient grounding of the shielding film 500, the first external connection terminal 160, the first substrate connection bump 181, the first through-electrode 245, and the first interposer substrate pad 271 are each located in the lateral direction of the first chip 300, the lateral direction of the second chip 400, and between the first chip 300 and the second chip 400, electromagnetic interference between the first chip 300 and the second chip 400 may be efficiently prevented.

FIG. 3 is a schematic diagram schematically showing embodiments of the first chip 300 of FIG. 2. Hereinafter, descriptions that are the same as those given with reference to FIGS. 1 and 2 are omitted, and the differences are mainly described.

Referring to FIG. 3, the first chip 300 may be a chip stacking structure. In this case, the first chip 300 may include a base chip 320, a first semiconductor chip 310, an adhesive layer 335, and a dummy chip 330. The base chip 320 may be a chip located at the bottommost position within the first chip 300. According to embodiments, at least one of the upper surface and the lower surface of the base chip 320 may have a flat shape.

According to embodiments, the base chip 320 may integrate signals of a plurality of first semiconductor chips 310 stacked above the base chip 320 and transmit the signals to the outside, or may transmit signals and power from the outside to the first semiconductor chips 310. Accordingly, the base chip 320 may also be referred to as a buffer chip or a control chip in the present specification.

The base chip 320 may include various types of individual devices. The individual devices may include various microelectronic devices, for example, metal-oxide-semiconductor field effect transistors (MOSFETs) such as complementary metal-oxide-semiconductor (CMOS) transistors, system large scale integrations (LSIs), image sensors such as CMOS imaging sensors (CISs), micro-electro-mechanical systems (MEMSs), active components, and passive components. In some embodiments, the base chip 320 may not include a memory cell. For example, a semiconductor device included in the base chip 320 may include a serial-parallel conversion circuit, a test logic circuit, such as design for test (DFT), Joint Test Action Group (JTAG), and memory builtin self-test (MBIST), and a signal interface circuit, such as PHY.

A through-electrode 325 that passes through the base chip 320 in the vertical direction (the Z-axis direction) may be located inside the base chip 320. The through-electrode 325 may be in contact with a base chip pad 321 located on the upper surface of the base chip 320. The through-electrode 325 may be electrically connected to the base chip pad 321.

The base chip pad 321 and a dielectric layer 323 may be located on the upper surface of the base chip 320. The dielectric layer 323 may surround the base chip pad 321. The dielectric layer 323 may surround a side surface of the base chip pad 321. The upper surface of the base chip pad 321 may be exposed vertically upward from the dielectric layer 323.

The first semiconductor chip 310 may be stacked on the base chip 320 in the vertical direction (the Z-axis direction). The first semiconductor chip 310 may be bonded on the base chip 320 through direct bonding. Examples of the direct bonding may include dielectric-to-dielectric bonding, copper-to-copper bonding, and hybrid bonding in which dielectric-to-dielectric bonding and metal-to-metal bonding occur together. The direct bonding may be diffusion bonding in which two interfaces containing the same material are placed to face one another, and then are brought into contact with one another and heat is applied to the two interfaces so that metal atoms or dielectric materials in contact with one another diffuse to form a single body. The hybrid bonding may include hybrid copper bonding.

The first semiconductor chip 310 may be bonded to the base chip 320 by direct bonding. For example, a semiconductor chip pad 311 and a dielectric layer 313 on the lower surface of the first semiconductor chip 310 may be in contact with a base chip pad 321 and a dielectric layer 323 on the upper surface of the base chip 320 in the vertical direction (the Z-axis direction). Specifically, the semiconductor chip pad 311 on the lower surface of the first semiconductor chip 310 may be in contact with the base chip pad 321 on the upper surface of the base chip 320 in the vertical direction (the Z-axis direction), and the dielectric layer 313 on the lower surface of the first semiconductor chip 310 may be in contact with the dielectric layer 323 on the upper surface of the base chip 320 in the vertical direction (the Z-axis direction). In this case, the semiconductor chip pad 311 and the dielectric layer 313 on the lower surface of the first semiconductor chip 310 may be bonded, by direct bonding, to the base chip pad 321 and the dielectric layer 323 on the upper surface of the base chip 320. In FIG. 1, it is illustrated that there is an interface between the semiconductor chip pad 311 and the dielectric layer 313 on the lower surface of the first semiconductor chip 310 and the base chip pad 321 and the dielectric layer 323 on the upper surface of the base chip 320. However, the interface may disappear when the semiconductor chip pad 311 and the dielectric layer 313 on the lower surface of the first semiconductor chip 310 are directly bonded to the base chip pad 321 and the dielectric layer 323 on the upper surface of the base chip 320.

According to embodiments, a plurality of first semiconductor chips 310 may be provided. The plurality of first semiconductor chips 310 may be defined as chips, which are stacked in the vertical direction (the Z-axis direction) on the base chip 320 and are located below the dummy chip 330, from among a plurality of chips included in the first chip 300. According to embodiments, the first semiconductor chip 310 may be referred to as a memory chip or a core chip.

According to embodiments, the first semiconductor chip 310 may include a semiconductor chip pad 311, a dielectric layer 313, and a through-electrode 315. The semiconductor chip pad 311 may be provided on each of the upper surface and the lower surface of the first semiconductor chip 310. The dielectric layer 313 may surround the semiconductor chip pad 311 on each of the upper surface and the lower surface of the first semiconductor chip 310. In this case, the dielectric layer 313 may cover the side surface of the semiconductor chip pad 311, and one of the upper surface and the lower surface of the semiconductor chip pad 311 may be exposed from the dielectric layer 313 in the vertical direction (the Z-axis direction).

The first semiconductor chip 310 may include a first semiconductor substrate. The first semiconductor substrate may have a lower surface and an upper surface that are opposite to one another. The lower surface may be a surface facing the interposer substrate 200. The lower surface may be referred to as an active surface, and the upper surface opposite to the lower surface may be referred to as an inactive surface.

The first semiconductor substrate may include silicon (Si), for example, crystalline silicon, polycrystalline silicon, or amorphous silicon. Alternatively, the first semiconductor substrate may include a semiconductor element, such as germanium (Ge), or a compound semiconductor, such as silicon carbide (SiC), gallium arsenide (GaAs), indium arsenide (InAs), or indium phosphide (InP). The first semiconductor substrate may have an SOI structure. For example, the first semiconductor substrate may include a BOX layer. The first semiconductor substrate may include a conductive region, for example, a well doped with impurities or a structure doped with impurities. In addition, the first semiconductor substrate may have various device isolation structures, such as a shallow trench isolation (STI) structure.

The first semiconductor chip 310 may include a first semiconductor device layer. According to embodiments, the first semiconductor device layer may be formed on a lower surface, which is an active surface of the first semiconductor substrate. The first semiconductor device layer may include a core region and a first dummy region. In the core region of the first semiconductor device layer, individual devices may be formed. The individual devices may include various microelectronic devices, for example, MOSFETs such as CMOS transistors, system LSIs, image sensors such as CISs, MEMSs, active components, and passive components.

The first semiconductor chip 310 may include a first wiring layer. The first wiring layer may be apart from the first semiconductor substrate in the vertical direction with the first semiconductor device layer therebetween. The first wiring layer may be electrically connected to the first semiconductor device layer. The first wiring layer may include wiring patterns each having a multilayer structure and a via connecting the wiring patterns to one another.

The through-electrode 315 may pass through the first semiconductor substrate of the first semiconductor chip 310 in the vertical direction (the Z-axis direction). The through-electrode 315 may pass through the first semiconductor device layer and the first semiconductor substrate. The through-electrode 315 may be electrically connected to the wiring patterns provided in the first wiring layer. The through-electrode 315 may have a tapered shape in which the horizontal width decreases or increases as the level in the vertical direction increases. At least a portion of the through-electrode 315 may have a pillar shape. The through-electrode 315 may be a TSV. According to embodiments, a first semiconductor chip 310_U located at the top from among the plurality of first semiconductor chips 310 may not include the through-electrode 315.

According to embodiments, the surface roughness of the upper surface of the first semiconductor chip 310_U located at the top may be greater than the surface roughness of the upper surfaces of other first semiconductor chips 310.

In some embodiments, the thickness of the first semiconductor chip 310_U located at the top from among the plurality of first semiconductor chips 310 in the vertical direction (the Z-axis direction) may be substantially the same as the thicknesses of the other first semiconductor chips 310 in the vertical direction (the Z-axis direction).

The plurality of first semiconductor chips 310 may be stacked in a row in the vertical direction (the Z-axis direction). For example, side surfaces of the plurality of first semiconductor chips 310 may be located on the same plane. However, the disclosed concept is not limited thereto, and the plurality of first semiconductor chips 310 may be offset-stacked in one direction.

In some embodiments, the plurality of first semiconductor chips 310 may be stacked in the vertical direction (the Z-axis direction) through direct bonding. For example, a semiconductor chip pad 311 and a dielectric layer 313 on the upper surface of one first semiconductor chip 310 may contact a semiconductor chip pad 311 and a dielectric layer 313 on the lower surface of another first semiconductor chip 310, located above the one first semiconductor chip 310, in the vertical direction (the Z-axis direction). Specifically, a semiconductor chip pad 311 on the upper surface of one first semiconductor chip 310 may contact a semiconductor chip pad 311 on the lower surface of another first semiconductor chip 310, located above the one first semiconductor chip 310, in the vertical direction (the Z-axis direction), and a dielectric layer 313 on the upper surface of one first semiconductor chip 310 may contact a dielectric layer 313 on the lower surface of another first semiconductor chip 310, located above the one first semiconductor chip 310, in the vertical direction (the Z-axis direction). In this case, the semiconductor chip pad 311 and the dielectric layer 313 on the upper surface of one first semiconductor chip 310 may be bonded, by direct bonding, to the semiconductor chip pad 311 and the dielectric layer 313 on the lower surface of another first semiconductor chip 310 located above the first semiconductor chip 310. In FIG. 3, it is illustrated that there is an interface between the semiconductor chip pad 311 and the dielectric layer 313 on the upper surface of the first semiconductor chip 310 and the semiconductor chip pad 311 and the dielectric layer 313 on the lower surface of the first semiconductor chip 310 located above the first semiconductor chip 310. However, the interface may disappear when the semiconductor chip pad 311 and the dielectric layer 313 on the upper surface of the first semiconductor chip 310 are directly bonded to the semiconductor chip pad 311 and the dielectric layer 313 on the lower surface of the first semiconductor chip 310 located above the first semiconductor chip 310.

As the first semiconductor chips 310 are stacked by direct bonding, an adhesive layer and a bump may not be between the plurality of first semiconductor chips 310.

According to embodiments, each of the first semiconductor chips 310 may include a memory chip. According to embodiments, the memory chip may be an HBM or a wire bonding memory package in which a plurality of memory chips are stacked in the vertical direction (the Z-axis direction). However, the disclosed concept is not limited thereto, and the semiconductor chip may include a microprocessor, such as a CPU, a GPU, or an AP, an analog device, or a logic chip such as a digital signal processor.

The dummy chip 330 may be stacked in the vertical direction (the Z-axis direction) on the first semiconductor chip 310_U located at the top. The dummy chip 330 may be stacked on the first semiconductor chip 310_U located at the top through an adhesive layer 335. According to embodiments, the dummy chip 330 may not be electrically connected to the first semiconductor chip 310. In some embodiments, the thickness of the dummy chip 330 in the vertical direction (the Z-axis direction) may be greater than the thickness of the first semiconductor chip 310 in the vertical direction (the Z-axis direction).

The adhesive layer 335 may be located between the dummy chip 330 and the first semiconductor chip 310_U located at the top. In embodiments, the adhesive layer 335 may be a layer configured to attach the dummy chip 330 on the first semiconductor chip 310_U located at the top. The adhesive layer 335 may be a film having adhesive properties of its own. For example, the adhesive layer 335 may be a double-sided adhesive film. According to embodiments, the adhesive layer 335 may be a tape-shaped material layer, a liquid coating curable material layer, or a combination thereof. Additionally, the adhesive layer 335 may include a thermal setting structure, a thermal plastic, an ultraviolet (UV) cure material, or a combination thereof. The adhesive layer 335 may be referred to as a die attach film (DAF) or a non-conductive film (NCF).

A first molding member 391 may be formed on the upper surface of the base chip 320 to surround the first semiconductor chips 310 and the dummy chip 330. The first molding member 391 may be formed from a molding material such as epoxy molding compound (EMC) or a photosensitive material such as photoimagable encapsulant (PIE). In some embodiments, a portion of the first molding member 391 may be formed from an insulating material, such as a silicon oxide film, a silicon nitride film, or a silicon oxynitride film. However, it is not limited thereto, and the first molding member 391 may be formed from a thermosetting resin such as an epoxy resin, a thermoplastic resin such as a polyimide, or a resin including a reinforcing material such as an inorganic filler, specifically, Ajinomoto Build-up Film (ABF), FR-4, BT, etc. According to embodiments, the upper surface of the first molding member 391 may be coplanar with the upper surface of the dummy chip 330.

FIG. 4 is a schematic diagram schematically showing embodiments of the first chip of FIG. 2. Hereinafter, descriptions that are the same as those given with reference to FIG. 3 are omitted, and the differences are mainly described.

Referring to FIG. 4, a first chip 301 may be a chip stack structure. In this case, the first chip 301 may include a base chip 320, a first semiconductor chip 310, an adhesive layer 335, and a dummy chip 330.

An underfill material layer 327 may be located between the base chip 320 and the first semiconductor chip 310 and between the first semiconductor chips 310. In addition, the base chip 320 and the first semiconductor chip 310 may be connected to one another through a chip connection bump 329, and the first semiconductor chips 310 that are adjacent to one another in the vertical direction (the Z-axis direction) may be connected to one another through a chip connection bump 319. Unlike the first chip 300 of FIG. 3, the first chip 301 of FIG. 4 may be formed by stacking the base chip 320 and a plurality of first semiconductor chips 310 in a flip chip manner using bumps such as micro bumps.

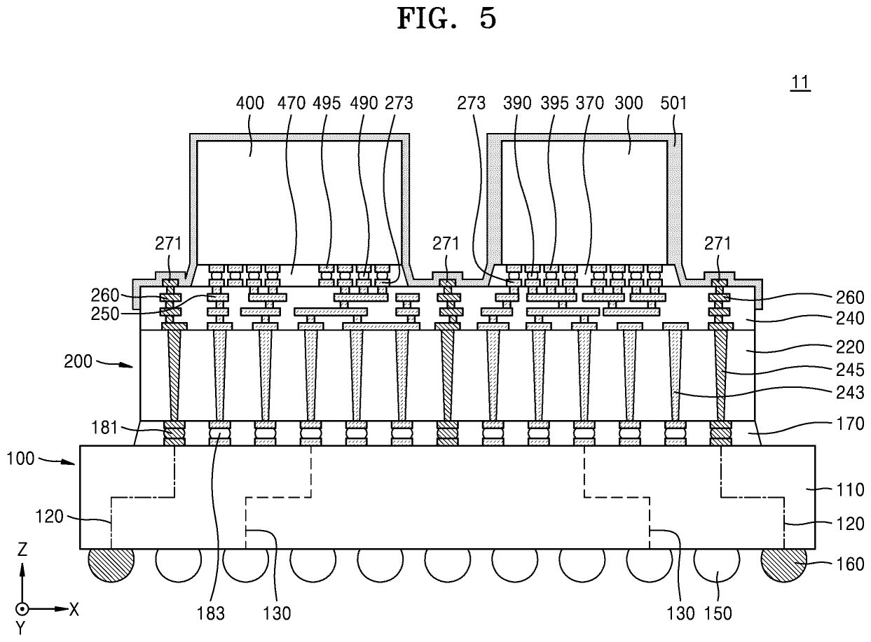

FIG. 5 is a schematic cross-sectional view of a semiconductor package according to embodiments. Hereinafter, descriptions that are the same as those given with reference to FIGS. 1 to 4 are omitted, and the differences are mainly described.

Referring to FIG. 5, a semiconductor package 11 may include an interposer substrate 200, a first chip 300, a second chip 400, and a shielding film 501. A package substrate 100 may be located below the interposer substrate 200 and may be electrically connected to the interposer substrate 200 and each of external connection terminals 150 and 160. The package substrate 100 may include wiring patterns 120 and 130 and an insulating layer 110. The wiring patterns 120 and 130 may include a first wiring pattern 120 that transmits a ground signal, and a second wiring pattern 130 that transmits power/a signal. According to embodiments, the second wiring pattern 130 may transmit other signals in addition to the power/signal. External connection terminals 150 and 160 may be located on the lower surface of the package substrate 100. The external connection terminals 150 and 160 may include a first external connection terminal 160 connected to the first wiring pattern 120, and a second external connection terminal 150 connected to the second wiring pattern 130.

The interposer substrate 200 may be mounted on the package substrate 100. An underfill material layer 170 may be arranged between the interposer substrate 200 and the package substrate 100 to surround substrate connection bumps 181 and 183. The substrate connection bumps 181 and 183 may include a first substrate connection bump 181 connected to the first wiring pattern 120, and a second substrate connection bump 183 connected to the second wiring pattern 130. The interposer substrate 200 may include a body 220, through-electrodes 243 and 245, a redistribution insulating layer 240, and redistribution patterns 250 and 260. The through-electrodes 243 and 245 may include a first through-electrode 245 connected to the first substrate connection bump 181, and a second through-electrode 243 connected to the second substrate connection bump 183.

The redistribution insulating layer 240 may be located on the upper surface of the body 220. The redistribution insulating layer 240 may surround at least portions of the redistribution patterns 250 and 260. The redistribution patterns 250 and 260 may include a first redistribution pattern 260 connected to the first through-electrode 245, and a second redistribution pattern 250 connected to the second through-electrode 243.

According to embodiments, the interposer substrate pads 271 and 273 may include a first interposer substrate pad 271 connected to the first redistribution pattern 260, and a second interposer substrate pad 273 connected to the second redistribution pattern 25.

The first chip 300 may be located on the interposer substrate 200. According to embodiments, the first chip 300 may be mounted on the interposer substrate 200 in a flip chip manner through the first chip connection bump 390, such as a micro bump, and a first chip pad 395. According to embodiments, an underfill material layer 370 may be arranged between the first chip 300 and the interposer substrate 200 to surround the first chip connection bump 390.

The second chip 400 may be apart from the first chip 300 in the horizontal direction (the X-axis direction and/or the Y-axis direction) and mounted on the interposer substrate 200. The second chip 400 may be mounted on the interposer substrate 200 in a flip chip manner through the second chip connection bump 490, such as a micro bump, and a second chip pad 495. According to embodiments, an underfill material layer 470 may be arranged between the second chip 400 and the interposer substrate 200 to surround the second chip connection bump 490.

The shielding film 501 may cover the upper surface of the interposer substrate 200, at least a portion of the side surface of the redistribution insulating layer 240, a surface of the first chip 300 exposed from the underfill material layer 470, and a surface of the second chip 400 exposed from the underfill material layer 370. The shielding film 501 may cover at least a portion of the side surface of the redistribution insulating layer 240. Accordingly, the shielding film 501 in contact with the side surface of the redistribution insulating layer 240 may have a shape extending upward in the vertical direction (the Z-axis direction).

The shielding film 501 may cover the first interposer substrate pad 271. Because the first interposer substrate pad 271 protrudes upward in the vertical direction (the Z-axis direction) from the redistribution insulating layer 240, the shielding film 501 covering the first interposer substrate pad 271 may be located at a higher vertical level than the shielding film 501 covering the upper surface of the redistribution insulating layer 240. Because the shielding film 501 covers the side surface of the first interposer substrate pad 271, the shielding film 501 that comes into lateral contact with the first interposer substrate pad 271 may have a shape that extends in the vertical direction (the Z-axis direction).

The shielding film 501 may cover the surfaces exposed by the underfill material layers 370 and 470 from each of the interposer substrate 200, the first chip 300, and the second chip 400. In this case, the shielding film 501 covering the underfill material layers 370 and 470 may have a slope. The slope may form a certain angle with the upper surface of the interposer substrate 200.

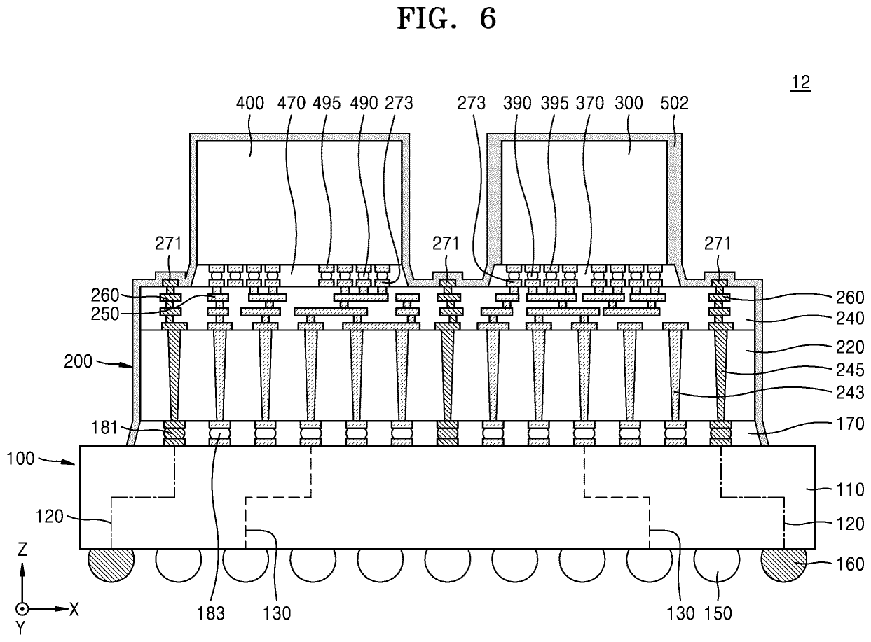

FIG. 6 is a schematic cross-sectional view of a semiconductor package according to embodiments. Hereinafter, descriptions that are the same as those given with reference to FIGS. 1 to 5 are omitted, and the differences are mainly described.

Referring to FIG. 6, a semiconductor package 12 may include an interposer substrate 200, a first chip 300, a second chip 400, and a shielding film 502. A package substrate 100 may be located below the interposer substrate 200 and may be electrically connected to the interposer substrate 200 and each of external connection terminals 150 and 160. The package substrate 100 may include wiring patterns 120 and 130 and an insulating layer 110. The wiring patterns 120 and 130 may include a first wiring pattern 120 that transmits a ground signal, and a second wiring pattern 130 that transmits power/a signal. According to embodiments, the second wiring pattern 130 may transmit other signals in addition to the power/signal. External connection terminals 150 and 160 may be located on the lower surface of the package substrate 100. The external connection terminals 150 and 160 may include a first external connection terminal 160 connected to the first wiring pattern 120, and a second external connection terminal 150 connected to the second wiring pattern 130.

The interposer substrate 200 may be mounted on the package substrate 100. An underfill material layer 170 may be arranged between the interposer substrate 200 and the package substrate 100 to surround substrate connection bumps 181 and 183. The substrate connection bumps 181 and 183 may include a first substrate connection bump 181 connected to the first wiring pattern 120, and a second substrate connection bump 183 connected to the second wiring pattern 130. The interposer substrate 200 may include a body 220, through-electrodes 243 and 245, a redistribution insulating layer 240, and redistribution patterns 250 and 260. The through-electrodes 243 and 245 may include a first through-electrode 245 connected to the first substrate connection bump 181, and a second through-electrode 243 connected to the second substrate connection bump 183.

The redistribution insulating layer 240 may be located on the upper surface of the body 220. The redistribution insulating layer 240 may surround at least portions of the redistribution patterns 250 and 260. The redistribution patterns 250 and 260 may include a first redistribution pattern 260 connected to the first through-electrode 245, and a second redistribution pattern 250 connected to the second through-electrode 243.

According to embodiments, the interposer substrate pads 271 and 273 may include a first interposer substrate pad 271 connected to the first redistribution pattern 260, and a second interposer substrate pad 273 connected to the second redistribution pattern 25.

The first chip 300 may be located on the interposer substrate 200. According to embodiments, the first chip 300 may be mounted on the interposer substrate 200 in a flip chip manner through the first chip connection bump 390, such as a micro bump, and a first chip pad 395. According to embodiments, an underfill material layer 370 may be arranged between the first chip 300 and the interposer substrate 200 to surround the first chip connection bump 390.

The second chip 400 may be apart from the first chip 300 in the horizontal direction (the X-axis direction and/or the Y-axis direction) and mounted on the interposer substrate 200. The second chip 400 may be mounted on the interposer substrate 200 in a flip chip manner through the second chip connection bump 490, such as a micro bump, and a second chip pad 495. According to embodiments, an underfill material layer 470 may be arranged between the second chip 400 and the interposer substrate 200 to surround the second chip connection bump 490.

The shielding film 502 may cover the upper surface and side surface of the interposer substrate 200, a surface of the underfill material layer 170 exposed from each of the interposer substrate 200 and the package substrate 100, at least a portion of the side surface of the redistribution insulation layer 240, a surface of the first chip 300 exposed from the underfill material layer 470, and a surface of the second chip 400 exposed from the underfill material layer 370.

Because the shielding film 502 covers the upper surface and side surface of the interposer substrate 200, electromagnetic interference generated from the interposer substrate 200 may be prevented.

The shielding film 502 may cover the first interposer substrate pad 271. Because the first interposer substrate pad 271 protrudes upward in the vertical direction (the Z-axis direction) from the redistribution insulating layer 240, the shielding film 502 covering the first interposer substrate pad 271 may be located at a higher vertical level than the shielding film 502 covering the upper surface of the redistribution insulating layer 240. Because the shielding film 502 covers the side surface of the first interposer substrate pad 271, the shielding film 502 that comes into lateral contact with the first interposer substrate pad 271 may have a shape that extends in the vertical direction (the Z-axis direction).

The shielding film 502 may cover the surfaces exposed by the underfill material layers 370 and 470 from each of the interposer substrate 200, the first chip 300, and the second chip 400. In this case, the shielding film 501 covering the underfill material layers 370 and 470 may have a slope. The slope may form a certain angle with the upper surface of the interposer substrate 200.

In addition, the shielding film 502 may cover the surface of the underfill material layer 170 exposed from the interposer substrate 200 and the package substrate 100. Accordingly, the shielding film 502 may cover the side surface of the underfill material layer 170. In this case, the shielding film 502 covering the side surface of the underfill material layer 170 may form a slope with the upper surface of the package substrate 100. The slope may form a certain angle with the upper surface of the package substrate 100.

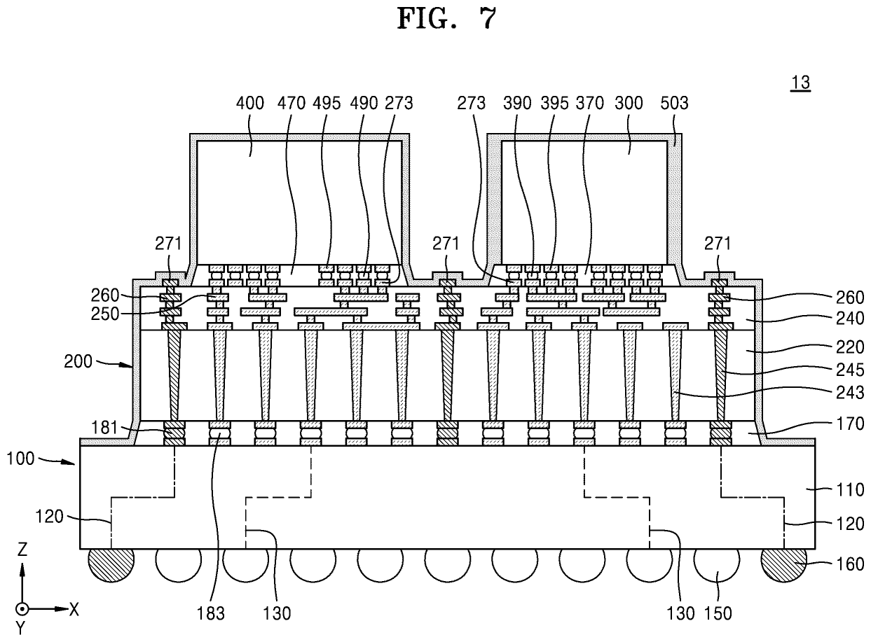

FIG. 7 is a schematic cross-sectional view of a semiconductor package according to embodiments. Hereinafter, descriptions that are the same as those given with reference to FIGS. 1 to 6 are omitted, and the differences are mainly described.

A semiconductor package 13 of FIG. 7 may include an interposer substrate 200, a first chip 300, a second chip 400, and a shielding film 503. Unlike in the semiconductor package 12 of FIG. 6, the shielding film 503 may cover the upper surface of the package substrate 100. Because the shielding film 503 covers the upper surface of the package substrate 100, electromagnetic interference effects generated from the package substrate 100 may be prevented.

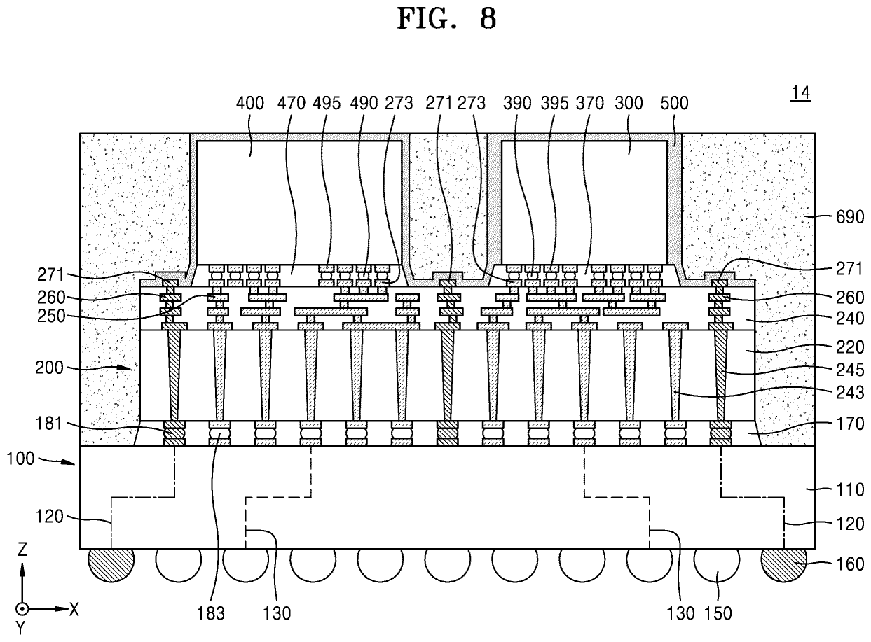

FIG. 8 is a schematic cross-sectional view of a semiconductor package according to embodiments. Hereinafter, descriptions that are the same as those given with reference to FIGS. 1 to 7 are omitted.

Referring to FIG. 8, a semiconductor package 14 may include an interposer substrate 200, a first chip 300, a second chip 400, a shielding film 500, and a second molding member 690. The second molding member 690 may surround the shielding film 500, the interposer substrate 200, and a package substrate 100. The second molding member 690 may also be filled between the first chip 300 and the second chip 400. The shielding film 500 and the second molding member 690 may be located between the first chip 300 and the second chip 400.

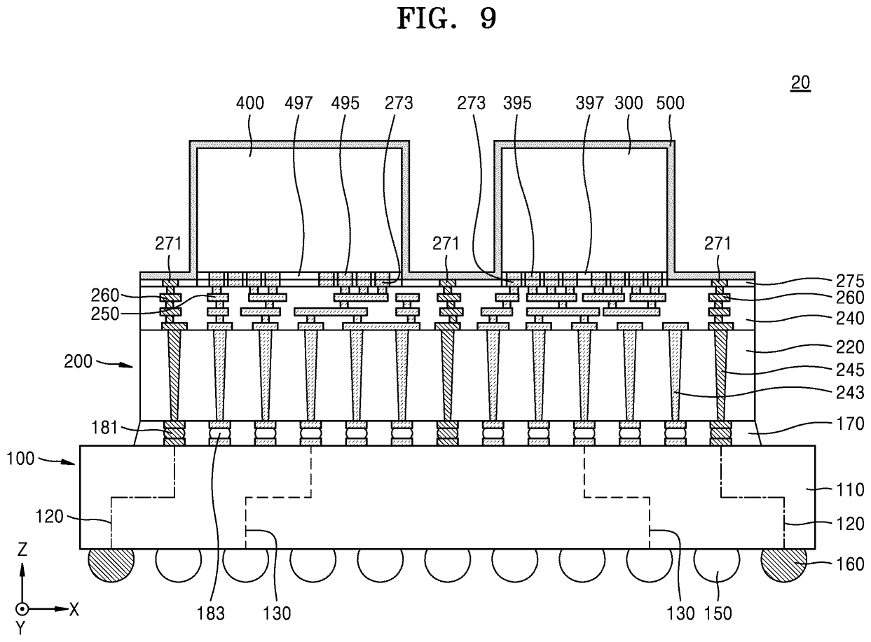

FIG. 9 is a schematic cross-sectional view of a semiconductor package according to embodiments. Hereinafter, descriptions that are the same as those given with reference to FIGS. 1 to 8 are omitted, and the differences are mainly described.

Referring to FIG. 9, a semiconductor package 20 may include an interposer substrate 200, a first chip 300, a second chip 400, and a shielding film 500. Each of the first chip 300 and the second chip 400 may be bonded to the interposer substrate 200 by direct bonding. Examples of the direct bonding may include dielectric-to-dielectric bonding, copper-to-copper bonding, and hybrid bonding in which dielectric-to-dielectric bonding and metal-to-metal bonding occur together. The direct bonding may be diffusion bonding in which two interfaces containing the same material are placed to face one another, and then are brought into contact with one another and heat is applied to the two interfaces so that metal atoms or dielectric materials in contact with one another diffuse to form a single body.

According to embodiments, a first chip pad 395 and a second interposer substrate pad 273 may be in contact with one another in the vertical direction (the Z-axis direction). A first chip bonding insulating layer 397 may be in contact with a bonding insulating layer 275 located on a redistribution insulating layer 240 in the vertical direction (the Z-axis direction).

According to embodiments, a second chip pad 495 and a second interposer substrate pad 273 may be in contact with one another in the vertical direction (the Z-axis direction). A second chip bonding insulating layer 497 may be in contact with the bonding insulating layer 275 located on the redistribution insulating layer 240 in the vertical direction (the Z-axis direction).

The bonding insulating layer 275 may surround the side surfaces of the first interposer substrate pad 271 and the second interposer substrate pad 273. Accordingly, the upper surface of the first interposer substrate pad 271, the upper surface of the second interposer substrate pad 273, and the upper surface of the bonding insulation layer 275 may form a coplanar surface.

The shielding film 500 may cover the upper surfaces of the first chip 300, the second chip 400, and the bonding insulation layer 275. The shielding film 500 may cover the upper surface of the first interposer substrate pad 271. In this case, because the upper surface of the first interposer substrate pad 271 forms a coplanar surface with the upper surface of the bonding insulation layer 275, the vertical level of the shielding film 500 covering the upper surface of the first interposer substrate pad 271 may be located at the same vertical level as the shielding film 500 covering the bonding insulation layer 275.

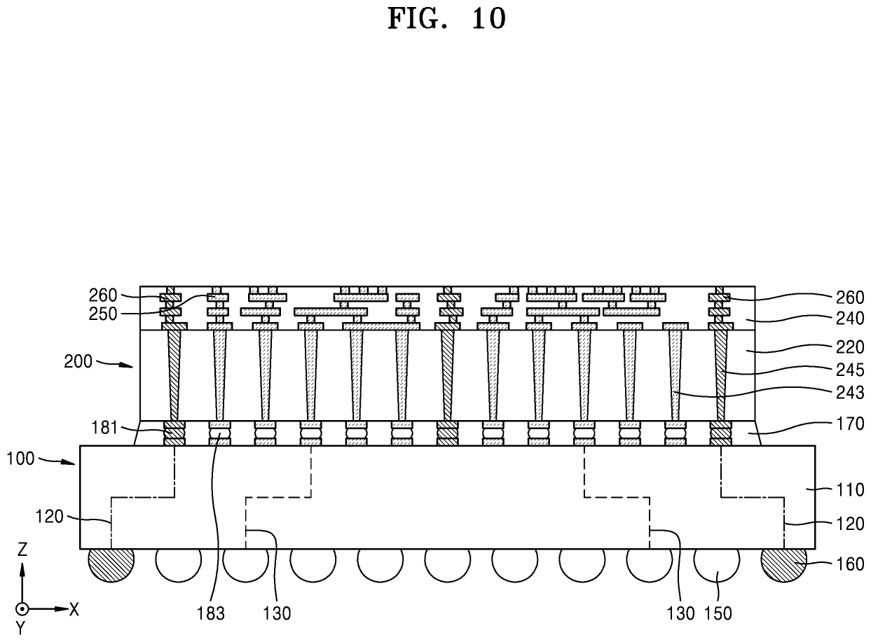

FIGS. 10 to 12 are cross-sectional views illustrating a method of manufacturing a semiconductor package, according to embodiments. Hereinafter, descriptions that are the same as those given with reference to FIGS. 1 to 9 are omitted, and the differences are mainly described.

Referring to FIG. 10, a package substrate 100 and an interposer substrate 200 electrically connected to and mounted on the package substrate 100 are provided. The package substrate 100 and the interposer substrate 200 may be electrically connected to one another by substrate connection bumps 181 and 183. The interposer substrate 200 may include a body 220, through-electrodes 243 and 245, a redistribution insulating layer 240, and redistribution patterns 250 and 260.

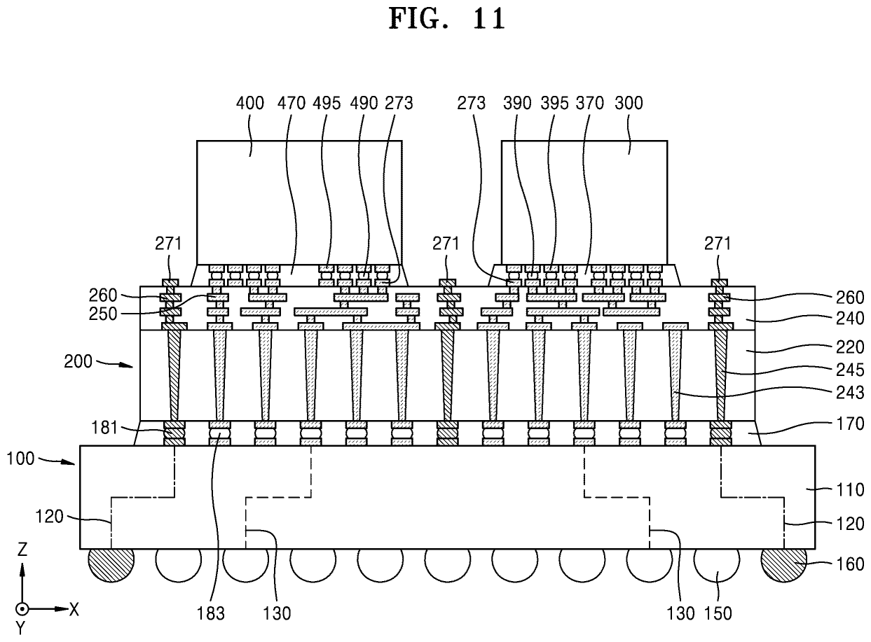

Referring to FIG. 11, interposer substrate pads 271 and 273 are formed on the interposer substrate 200, and a first chip 300 and a second chip 400 are mounted. The first chip 300 and the second chip 400 may be mounted on the interposer substrate 200 in a flip chip manner, as illustrated in FIG. 11. In some embodiments, the first chip 300 and the second chip 400 may be mounted on the interposer substrate 200 by direct bonding, as described with reference to FIG. 9.

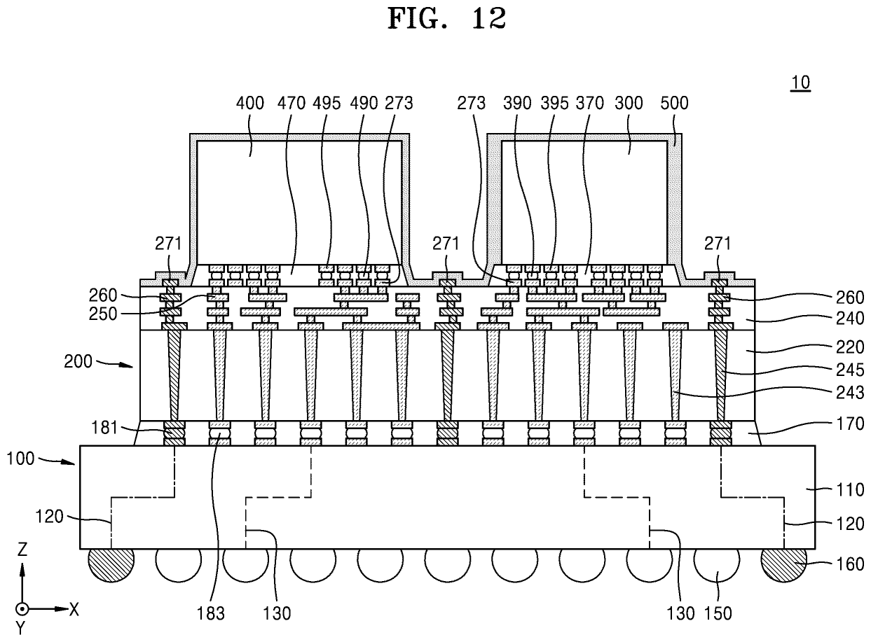

Referring to FIG. 12, a shielding film 500 covering the upper surface of the interposer substrate 200, the first chip 300, and the second chip 400 is formed. The shielding film 500 may be formed through a sputtering process or a spray coating process. The shielding film 500 may be connected to the first interposer substrate pad 271 and may be connected to the ground through the first interposer substrate pad 271, the first redistribution pattern 260, the first through-electrode 245, the first substrate connection bump 181, a first wiring pattern 120, and a first external connection terminal 160.

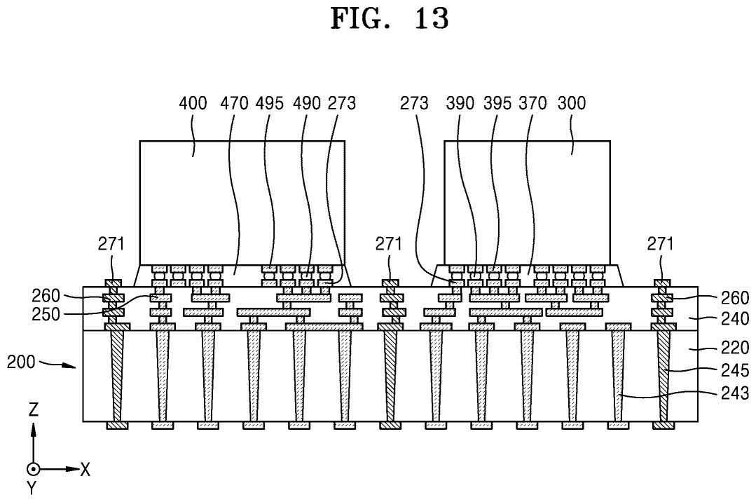

FIGS. 13 to 15 are cross-sectional views illustrating a method of manufacturing a semiconductor package, according to embodiments. Hereinafter, descriptions that are the same as those given with reference to FIGS. 1 to 12 are omitted, and the differences are mainly described.

Referring to FIG. 13, an interposer substrate 200, and a first chip 300 and a second chip 400 mounted on the interposer substrate 200 are provided. The first chip 300 and the second chip 400 may be mounted on the interposer substrate 200 by a flip chip method or a direct bonding method.

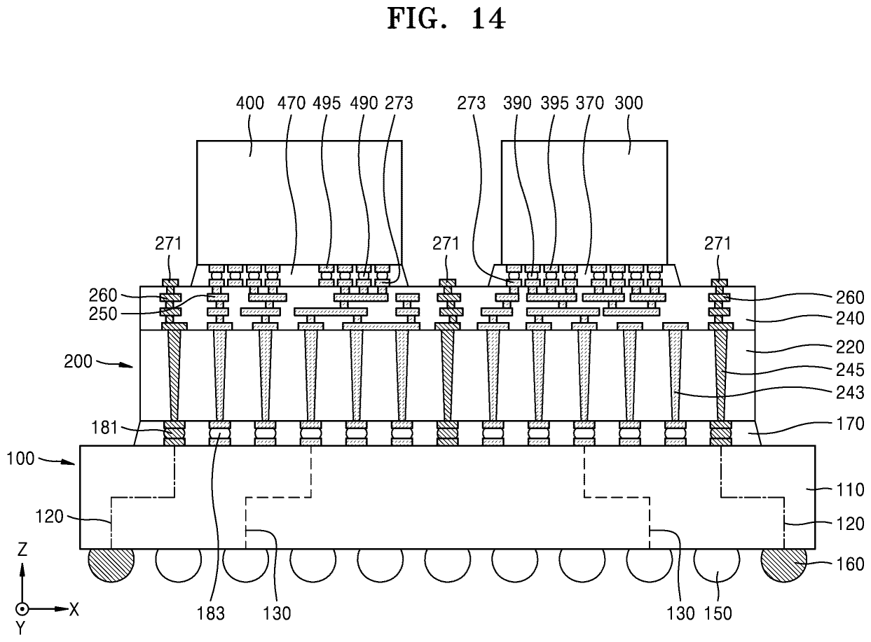

Referring to FIG. 14, a package substrate 100 is mounted on the lower surface of the interposer substrate 200. The package substrate 100 may be mounted on the lower surface of the interposer substrate 200 through substrate connection bumps 181 and 183.

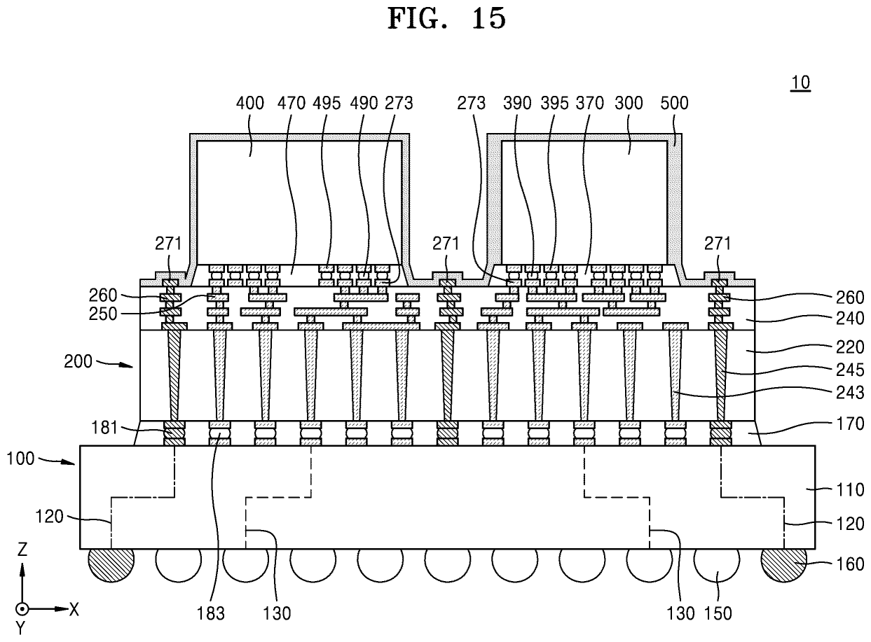

Referring to FIG. 15, a shielding film 500 covering the upper surface of the interposer substrate 200, the first chip 300, and the second chip 400 is formed. The shielding film 500 may be connected to a first interposer substrate pad 271 and may be connected to the ground through the first interposer substrate pad 271, a first redistribution pattern 260, a first through-electrode 245, a first substrate connection bump 181, a first wiring pattern 120, and a first external connection terminal 160.

While the disclosed concepts have been particularly shown and described with reference to embodiments thereof, it will be understood that various changes in form and details may be made therein without departing from the spirit and scope of the following claims.

What is claimed is:

1. A semiconductor package comprising:
a package substrate including a wiring pattern;
an interposer substrate located on the package substrate and including a body, a through-electrode passing through the body, a redistribution pattern connected to the through-electrode, a redistribution insulating layer surrounding at least a portion of the redistribution pattern, and an interposer substrate pad;
a first chip on the interposer substrate;
a second chip spaced apart from the first chip in a horizontal direction on the interposer substrate; and
a shielding film covering an exposed surface of the first chip and an exposed surface of the second chip,
wherein the through-electrode includes a ground through-electrode,
the redistribution pattern includes a ground redistribution pattern,
the interposer substrate pad includes a ground interposer substrate pad, and
the shielding film is in contact with the ground interposer substrate pad.

2. The semiconductor package of claim 1, wherein the shielding film covers an upper surface of the interposer substrate, and a portion of the shielding film that covers the ground interposer substrate pad is located at a higher vertical level than a portion of the shielding film that covers an upper surface of the redistribution insulating layer.

3. The semiconductor package of claim 1, wherein a ground substrate connection bump that transmits a ground signal is located between the interposer substrate and the package substrate, a ground external connection terminal that transmits a ground signal is located on a lower surface of the package substrate, and each of the ground interposer substrate pad, the ground through-electrode, the ground substrate connection bump, and the ground external connection terminal is located in a lateral direction of the first chip, in a lateral direction of the second chip, and between the first chip and the second chip.

4. The semiconductor package of claim 1, wherein the first chip is located on the interposer substrate through a first chip connection bump, the second chip is located on the interposer substrate through a second chip connection bump, and an underfill material layer is located between the first chip and the interposer substrate and between the second chip and the interposer substrate.

5. The semiconductor package of claim 4, wherein the shielding film covers the underfill material layer, and the shielding film in contact with the underfill material layer has a slope forming a certain angle with an upper surface of the interposer substrate.

6. The semiconductor package of claim 1, wherein a bonding insulating layer is located on an upper surface of the redistribution insulating layer, the bonding insulating layer covers a side surface of the interposer substrate pad, a first chip pad and a first chip bonding insulating layer covering a side surface of the first chip pad are located on a lower surface of the first chip, a second chip pad and a second chip bonding insulating layer covering a side surface of the second chip pad are located on a lower surface of the second chip, and the first chip pad and the second chip pad are each in contact with the interposer substrate pad in a vertical direction.

7. The semiconductor package of claim 6, wherein an upper surface of the bonding insulating layer is coplanar with an upper surface of the interposer substrate pad, and the shielding film covers the upper surface of the bonding insulating layer and the upper surface of the interposer substrate pad.

8. The semiconductor package of claim 1, wherein the shielding film covers at least a portion of a side surface of the redistribution insulating layer.

9. The semiconductor package of claim 1, wherein a substrate connection bump and an underfill material layer surrounding the substrate connection bump are located between the interposer substrate and the package substrate.

10. The semiconductor package of claim 9, wherein the shielding film covers an upper surface and a side surface of the interposer substrate and a side surface of the underfill material layer located between the interposer substrate and the package substrate.

11. The semiconductor package of claim 1, wherein the shielding film covers an upper surface and a side surface of the interposer substrate and an upper surface of the package substrate.

12. A semiconductor package comprising:
a package substrate including a first wiring pattern and a second wiring pattern;
a first external connection terminal and a second external connection terminal located on a lower surface of the package substrate;
an interposer substrate located on an upper surface of the package substrate, the interposer substrate including a body, a first through-electrode and a second through-electrode passing through the body, a first redistribution pattern electrically connected to the first through-electrode, a second redistribution pattern electrically connected to the second through-electrode, a redistribution insulating layer, a first interposer substrate pad connected to the first redistribution pattern on the redistribution insulating layer, and a second interposer substrate pad connected to the second redistribution pattern on the redistribution insulating layer;
a first substrate connection bump and a second substrate connection bump located between the package substrate and the interposer substrate;
a first chip on the interposer substrate;
a second chip spaced apart from the first chip in a horizontal direction on the interposer substrate; and
a shielding film covering an upper surface of the interposer substrate, an upper surface and a side surface of the first chip, and an upper surface and a side surface of the second chip,
wherein the first wiring pattern, the first external connection terminal, the first through-electrode, the first redistribution pattern, the first substrate connection bump, and the first interposer substrate pad transmit a ground signal.

13. The semiconductor package of claim 12, wherein each of the first interposer substrate pad, the first through-electrode, the first substrate connection bump, and the first external connection terminal is located in a lateral direction of the first chip, in a lateral direction of the second chip, and between the first chip and the second chip.

14. The semiconductor package of claim 12, wherein the first chip is located on the interposer substrate through a first chip connection bump, the second chip is located on the interposer substrate through a second chip connection bump, and an underfill material layer is located between the first chip and the interposer substrate and between the second chip and the interposer substrate,
wherein the shielding film covers the underfill material layer, and the shielding film covering the underfill material layer has a slope forming a certain angle with an upper surface of the interposer substrate.

15. The semiconductor package of claim 12, wherein a bonding insulating layer is located on an upper surface of the redistribution insulating layer, the bonding insulating layer covers a side surface of the interposer substrate pad, a first chip pad and a first chip bonding insulating layer covering a side surface of the first chip pad are located on a lower surface of the first chip, a second chip pad and a second chip bonding insulating layer covering a side surface of the second chip pad are located on a lower surface of the second chip, and the first chip pad and the second chip pad are each in contact with the interposer substrate pad in a vertical direction,
wherein an upper surface of the bonding insulating layer is coplanar with an upper surface of the interposer substrate, and the shielding film covers the upper surface of the bonding insulating layer and the upper surface of the interposer substrate.

16. The semiconductor package of claim 12, wherein a portion of the shielding film that covers the ground interposer substrate pad is located at a higher vertical level than a portion of the shielding film that covers an upper surface of the redistribution insulating layer.

17. The semiconductor package of claim 12, wherein the first chip includes a chip stack structure in which a base chip and a plurality of first semiconductor chips are stacked in a vertical direction.

18. A semiconductor package comprising:
a package substrate including a first wiring pattern and a second wiring pattern;
a first external connection terminal and a second external connection terminal located on a lower surface of the package substrate;
an interposer substrate located on an upper surface of the package substrate, the interposer substrate including a body, a first through-electrode and a second through-electrode passing through the body, a first redistribution pattern electrically connected to the first through-electrode, a second redistribution pattern electrically connected to the second through-electrode, a redistribution insulating layer, a first interposer substrate pad connected to the first redistribution pattern on the redistribution insulating layer, and a second interposer substrate pad connected to the second redistribution pattern on the redistribution insulating layer;
a first substrate connection bump and a second substrate connection bump located between the package substrate and the interposer substrate;
an underfill material layer surrounding the first substrate connection bump and the second substrate connection bump;
a first chip on the interposer substrate;
a second chip spaced apart from the first chip in a horizontal direction on the interposer substrate;
a shielding film covering an upper surface of the interposer substrate, an upper surface and a side surface of the first chip, and an upper surface and a side surface of the second chip; and
a molding member covering an upper surface of the package substrate, a side surface and an upper surface of the interposer substrate, and the shielding film,
wherein the first wiring pattern, the first external connection terminal, the first through-electrode, the first redistribution pattern, the first substrate connection bump, and the first interposer substrate pad transmit a ground signal, the shielding film and the molding member are located between the first chip and the second chip, and each of the first interposer substrate pad, the first through-electrode, the first substrate connection bump, and the first external connection terminal does not overlap each of the first chip and the second chip in a vertical direction.

19. The semiconductor package of claim 18, wherein a bonding insulating layer is located on an upper surface of the redistribution insulating layer, the bonding insulating layer covers a side surface of the interposer substrate pad, a first chip pad and a first chip bonding insulating layer covering a side surface of the first chip pad are located on a lower surface of the first chip, a second chip pad and a second chip bonding insulating layer covering a side surface of the second chip pad are located on a lower surface of the second chip, and the first chip pad and the second chip pad are each in contact with the interposer substrate pad in a vertical direction,
wherein an upper surface of the bonding insulating layer is coplanar with an upper surface of the interposer substrate, and the shielding film covers the upper surface of the bonding insulating layer and the upper surface of the interposer substrate.

20. The semiconductor package of claim 18, wherein a portion of the shielding film that covers the ground interposer substrate pad is located at a higher vertical level than a portion of the shielding film that covers an upper surface of the redistribution insulating layer.
